(19) United States
(12) Patent Application Publication
(10) Pub. No.: US 2024/0193342 A1
(43) Pub. Date: Jun. 13, 2024

(54) Field-Programmable Gate Array (FPGA) Routing Congestion Prediction Method and System

(71) Applicants: BEIJING MICROELECTRONICS TECHNOLOGY INSTITUTE, Beijing (CN); BEIJING MXTRONICS TECHNOLOGY CO., LTD, Beijing (CN)

(72) Inventors: Chunsheng TIAN, Beijing (CN); Lei CHEN, Beijing (CN); Shuo WANG, Beijing (CN); Jing ZHOU, Beijing (CN); Yongjiang PANG, Beijing (CN); Chong ZHOU, Beijing (CN); Xiaojing MA, Beijing (CN); Yaowei ZHANG, Beijing (CN); Zhong DU, Beijing (CN); Lu ZHANG, Beijing (CN); Peipei XI, Beijing (CN)

(21) Appl. No.: 18/284,585

(22) PCT Filed: Aug. 13, 2021
(86) PCT No.: PCT/CN2021/112384

§ 371 Date: Sep. 28, 2023

(30) Foreign Application Priority Data
Jun. 22, 2021 (CN) 202110691125.3

(51) Int. Cl. G06F 30/398; G06F 30/394

(52) U.S. Cl. CPC G06F 30/398; G06F 30/394

(57) ABSTRACT

The disclosure relates to a Field-Programmable Gate Array (FPGA) routing congestion prediction method and system. The method includes: first, an FPGA routing congestion prediction problem is modeled as an image conversion problem; feature information parameters are extracted according to the image conversion problem; and a cycle-consistency generative adversarial network model is defined to solve the image conversion problem, and a result of routing congestion prediction is obtained. Through the FPGA routing congestion prediction method and system designed by the disclosure, the result of routing congestion can be accurately predicted according to a series of intermediate and result files in a placement stage, thus reducing the time needed for routing iteration, further improving the working efficiency of an FPGA Electronic Design Automation (EDA) tool, and providing strong support for a healthy and sustainable development of the FPGA.

The disclosure claims priority to Chinese Patent Application No. 202110691125.3 filed to the China National Intellectual Property Administration on Jun. 22, 2021 and entitled “Field-Programmable Gate Array (FPGA) Routing Congestion Prediction Method and System”, the disclosure of which is hereby incorporated by reference in its entirety.

### TECHNICAL FIELD

The disclosure relates to an FPGA routing congestion prediction method and system, belonging to the field of integrated circuit design automation.

### BACKGROUND

As a semi-custom circuit, FPGA has been widely applied to high-performance computing, Internet of Things, aerospace, artificial intelligence and other fields due to its short development cycle, flexible design, low development cost, etc. However, with the continuous development of science and technology, the device complexity and system capacity of the FPGA have been greatly improved, and new requirements are also made for the design process of an FPGA Electronic Design Automation (EDA) tool.

Through the EDA design tool, a to-be-implemented circuit or system function can be compiled into a binary code bitstream file. By using the binary code bitstream file, the state of an internal device of the FPGA can be configured, so that a required function can be implemented on an FPGA chip. However, with the continuous improvement of the circuit scale and the integration of the FPGA chip, time required for the EDA tool to compile an FPGA circuit is getting longer and longer, which seriously restricts the rapid development of the FPGA.

Routing is one of the most time-consuming steps in the FPGA EDA tool flow. How to accurately predict routing congestion and reduce the time needed for routing iteration is particularly important.

### SUMMARY

The disclosure aims to overcome the shortcomings of a conventional art, and provide an FPGA routing congestion prediction method and system. A result of routing congestion is accurately predicted in a placement stage, the difficulty in accurately predicting the result of FPGA routing congestion is solved, the time required for routing iteration is reduced, and the result quality and execution efficiency of an FPGA automatic placement and routing tool are improved.

In order to solve the above problem, at least some embodiments of the disclosure disclose the FPGA routing congestion prediction method and system.

The FPGA routing congestion prediction method includes the following steps.

Step S1, modeling FPGA routing congestion prediction: modeling an FPGA routing congestion prediction problem as an image conversion problem.

Step S2, extracting feature information parameters to obtain an image file after placement imgₚ.

Step S3, obtaining an image file after routing img, based on a routing result and converting the image file after routing imgᵣ into an image file capable of representing a result of FPGA routing congestion.

Step S4, defining a cycle-consistency generative adversarial network model to solve the image conversion problem, and a result of FPGA routing congestion prediction is obtained.

In some embodiments, the step S1, modeling the FPGA routing congestion prediction problem into the image conversion problem includes:
obtaining an image file after FPGA placement imgₚ based on a result file of FPGA placement;
obtaining an image file after FPGA routing img, based on a result file after FPGA routing;
wherein the image file after FPGA placement imgₚ and the image file after FPGA routing img, are multi-channel images.

Wherein, there is a one-to-one mapping relationship between the image file after FPGA placement imgₚ and the heat map imgᵣₕₘ representing the result of FPGA routing congestion, and the solution of the heat map imgᵣₕₘ is transformed into a process of generating the heat map imgᵣₕₘ representing the result of FPGA routing congestion by using the known image file after FPGA placement imgₚ, that is, completing the modeling of the FPGA routing congestion prediction problem.

In some embodiments, the step S2, extracting the feature information parameters to obtain the image file after placement imgₚ includes:
the feature information parameters include a connection relationship between netlists, pin density after placement and a macro module.

Generating feature images corresponding to each feature information parameter based on the feature information parameters, wherein the feature images comprise an image of the connection relationship between the netlists, an image of the pin density after placement and a macro module image;
wherein generating the image file after placement imgₚ based on the feature images includes:
stacking the image of the connection relationship between the netlists, the image of the pin density after placement and the macro module image to obtain the image file after placement imgₚ.

In some embodiments, the step S3 obtaining the image file after routing based on the routing result and converting the image file after routing img, into the heat map file imgᵣₕₘ capable of representing the result of FPGA routing congestion includes:
acquiring a result file after routing;
converting the result file after routing into the image file after routing img,;
transforming the image file after routing img, into the heat map file imgᵣₕₘ to represent the result of FPGA routing congestion.

In some embodiments, the step S4, defining the cycle-consistency generative adversarial network to solve the image conversion problem and obtaining the result of FPGA routing congestion prediction includes;
step S401, a loss function of the cycle-consistency generative adversarial network is defined as:

$$ℒ ( {G}_{{img}_{p}} , {F}_{{img}_{rhm}} , {Dis}_{{img}_{rhm}} , {Dis}_{{img}_{p}} ) = {ℒ}_{g a n} ( {G}_{{img}_{p}} , {Dis}_{{img}_{rhm}} , {X}_{{img}_{p}} , {Y}_{{img}_{rhm}} ) + {ℒ}_{gan} ( {F}_{{img}_{rhm}} , {Dis}_{{img}_{p}} , {Y}_{{img}_{rhm}} , {X}_{{img}_{p}} ) + λ {ℒ}_{c y c} ( {G}_{{img}_{p}} , {F}_{{img}_{rhm}} ) + {γℒ}_{dis} ( {G}_{{img}_{p}} , {F}_{{img}_{rhm}} ) \qquad ( 1 )$$

wherein [symbol] _{gan}(G_{img}_{ₚ}, Dis_{img}_{ᵣₕₘ}, X_{img}_{ₚ}, Y_{img}_{ᵣₕₘ}) represents a forward loss function of the cycle-consistency generative adversarial network, the forward loss function is expressed as:

$$\\ \begin{matrix}{ℒ}_{gan} ( {G}_{{img}_{p}} , {Dis}_{{img}_{rhm}} , {X}_{{img}_{p}} , {Y}_{{img}_{rhm}} ) = \frac{1}{2} {E}_{{y}_{{img}_{rhm}} \sim {P}_{data} ( {Y}_{{img}_{rhm}} )} [ {( {Dis}_{{img}_{rhm}} ( {y}_{{img}_{rhm}} ) - 1 )}^{2} ] + \frac{1}{2} {E}_{{x}_{{img}_{p}} \sim {P}_{data} ( {X}_{{img}_{p}} )} [ {( {Dis}_{{img}_{rhm}} ( {G}_{{img}_{p}} ( {x}_{{img}_{p}} ) ) )}^{2} ] & ( 2 )\end{matrix}$$

wherein Dis_{img}_{ᵣₕₘ} represents a forward discriminate function of the cycle-consistency generative adversarial network, G_{img}, represents a forward generation function of the cycle-consistency generative adversarial network, x_{img}, ∈X_{img}, represents a set of samples of the image file imgₚ after placement, P_{data}(X_{img}_{ₚ}) represents a distribution function of a sample X_{img}_{ₚ}, E represents mathematical expectation, y_{img}_{ᵣₕₘ} ∈Y_{img}_{ᵣₕₘ} represents a set of samples of the heat map file imgᵣₕₘ, and P_{data}(Y_{img}_{ᵣₕₘ}) represents the distribution function of a sample Y_{img}_{ᵣₕₘ}.

[symbol] _{gan}(F_{img}_{ᵣₕₘ}, Dis_{img}_{ₚ}, Y_{img}_{ᵣₕₘ}, X_{img}_{ₚ}) represents a reverse loss function of the cycle-consistency r generative adversarial network, the reverse loss function is expressed as:

$$\\ \begin{matrix}{ℒ}_{gan} ( {F}_{{img}_{rhm}} , {Dis}_{{img}_{p}} , {Y}_{{img}_{rhm}} , {X}_{{img}_{p}} ) = \frac{1}{2} {E}_{{x}_{{img}_{p}} \sim {P}_{data} ( {X}_{{img}_{p}} )} [ {( {Dis}_{{img}_{p}} ( {x}_{{img}_{p}} ) - 1 )}^{2} ] + \frac{1}{2} {E}_{{y}_{{img}_{rhm}} \sim {P}_{data} ( {Y}_{{img}_{rhm}} )} [ {( {Dis}_{{img}_{p}} ( {F}_{{img}_{rhm}} ( {y}_{{img}_{rhm}} ) ) )}^{2} ] & ( 3 )\end{matrix}$$

wherein F_{img}_{ᵣₕₘ} represents a reverse generation function of the cycle-consistency generative adversarial network, and Dis_{img}_{ₚ} represents a reverse discriminate function of the cycle-consistency generative adversarial network.

[symbol] _{cyc}(G_{img}_{ₚ}, F_{img}_{ᵣₕₘ}) represents consistency loss of the cycle-consistency generative adversarial network, the consistency loss is expressed as:

$$\\ \begin{matrix}{ℒ}_{cyc} ( {G}_{{img}_{p}} , {F}_{{img}_{rhm}} ) = {E}_{{y}_{{img}_{rhm}} \sim {p}_{data} ( {Y}_{{img}_{rhm}} )} {‖ {G}_{{img}_{p}} ( {F}_{{img}_{rhm}} ( {y}_{{img}_{rhm}} ) ) - {y}_{{img}_{rhm}} ‖}_{1} + {E}_{{x}_{{img}_{p}} \sim {p}_{data} ( {X}_{{img}_{p}} )} {‖ {F}_{{img}_{rhm}} ( {G}_{{img}_{p}} ( {x}_{{img}_{p}} ) ) - {x}_{{img}_{p}} ‖}_{1} & ( 4 )\end{matrix}$$

wherein [symbol] _{dis}(G_{img}_{ₚ}, F_{img}_{ᵣₕₘ}) represents a standard loss function of the cycle-consistency generative adversarial network, the standard loss function is expressed as:

$$\\ \begin{matrix}{ℒ}_{dis} ( {G}_{{img}_{p}} , {F}_{{img}_{rhm}} ) = {E}_{{x}_{{img}_{p}} , {y}_{{img}_{rhm}} \sim {p}_{data} ( {X}_{{img}_{p}} , {Y}_{{img}_{rhm}} )} {‖ {F}_{{img}_{rhm}} ( {y}_{{img}_{rhm}} ) - {x}_{{img}_{p}} ‖}_{1} + {E}_{{x}_{{img}_{p}} , {y}_{{img}_{rhm}} \sim {p}_{data} ( {X}_{{img}_{p}} , {Y}_{{img}_{rhm}} )} {‖ {G}_{{img}_{p}} ( {x}_{{img}_{p}} ) - {y}_{{img}_{rhm}} ‖}_{1} . & ( 5 )\end{matrix}$$

In the formula (1), λ and γ represent weight indicator factors, and both λ and γ are positive numbers.

Step S402, based on the definition, an objective function of the cycle-consistency generative adversarial network is represented as:

$$\\ \begin{matrix}{min}_{{G}_{{img}_{p}} , {F}_{{img}_{rhm}}} {min}_{{X}_{{img}_{p}} , {Y}_{{img}_{rhm}}} ℒ ( {G}_{{img}_{p}} , {F}_{{img}_{rhm}} , {Dis}_{{img}_{rhm}} , {Dis}_{{img}_{p}} ) . & ( 6 )\end{matrix}$$

Step S403, for the forward generation function G_{img}_{ₚ} and the reverse generation function F_{img}_{ᵣₕₘ}, a first neural network model is constructed for training. The first neural network model specifically includes m₁ convolution modules, an intensive residual network composed of n₁ residual modules and m₁ deconvolution modules, and both m₁ and n₁ are positive integers.

Step S404, for the reverse discriminate functions Dis_{img}_{ₚ} and the forward discriminate function Dis_{img}_{ᵣₕₘ}, a second neural network model is constructed for training. The second neural network model includes m₂ convolution modules, and m₂ is a positive integer.

Step S405, multiple image files after placement imgₚ and multiple heat map files imgᵣₕₘ capable of representing the result of FPGA routing congestion are enabled to form an overall sample set.
a). the overall sample set is divided into two parts of a training sample set and a verification sample set.
b). the first neural network model and the second neural network model are trained based on the training sample set, and in response to an objective function curve converges, completing the training to obtain an initial training model.
c). calibrating the initial training model by using the verification sample set to obtain a final training model.

Step S406, inputting the image file after placement img, into the obtained final training model to obtain the result of routing congestion prediction.

In some embodiments, the disclosure also provides an FPGA routing congestion prediction system, which includes: an FPGA core design module, an information preprocessing module and a cycle-consistency generative adversarial network module.

The FPGA core design module is configured to model an FPGA routing congestion prediction problem as an image conversion problem and complete modeling of FPGA routing congestion prediction.

The information preprocessing module is configured to extract required feature information parameters to obtain an image file after placement imgₚ and an image file after routing imgᵣ.

The cycle-consistency generative adversarial network module is configured to define a cycle-consistency generative adversarial network model to solve the image conversion problem, and obtain a result of FPGA routing congestion prediction.

In some embodiments, the system also includes a memory module, a display module and an information transfer module. The memory module is configured to store an intermediate file and a result file of routing congestion prediction, the display module is configured to display the result of routing congestion prediction, and the information transfer module is configured to transfer information among the memory module, the display module and information transfer module.

In some embodiments, the modeling the FPGA routing congestion prediction problem into the image conversion problem includes:
obtaining an image file after FPGA placement imgₚ based on a result file of FPGA placement;
obtaining an image file after FPGA routing imgᵣ based on a result file after FPGA routing;
   wherein the image file after FPGA placement imgₚ and the image file after FPGA routing imgᵣ are multi-channel images;
transforming the image file after FPGA routing img, into a heat map imgᵣₕₘ, and representing the result of FPGA routing congestion by the heat map imgᵣₕₘ.

There is a one-to-one mapping relationship between the image file after FPGA placement imgₚ and the heat map imgᵣₕₘ representing the result of FPGA routing congestion, and the solution of the heat map imgᵣₕₘ of the result of FPGA routing congestion is transformed into a process of generating the heat map imgᵣₕₘ of the result of FPGA routing congestion by using the known image file after FPGA placement imgₚ, that is, completing the modeling of the FPGA routing congestion prediction problem.

In some embodiments, extracting the feature information parameters to obtain the image file after placement imgₚ includes:

The feature information parameters include a connection relationship between netlists, pin density after placement and a macro module.
generating feature images corresponding to each feature information parameter based on the feature information parameters, wherein the feature images comprise an image of the connection relationship between the netlists, an image of the pin density after placement and a macro module image.

The operation of generating the image file after placement imgₚ based on the feature images includes:
stacking the image of the connection relationship between the netlists, the image of the pin density after placement and the macro module image to obtain the image file imgₚ after placement.

Wherein obtaining the image file after routing imgᵣ based on the routing result and converting the image file after routing imgᵣ into the image file imgᵣₕₘ capable of representing the result of

FPGA routing congestion includes:
acquiring a result file after routing;
converting the result file after routing into the image file after routing imgᵣ;
transforming the image file after routing imgᵣ into the heat map file imgᵣₕₘ to represent the result of FPGA routing congestion.

In some embodiments, defining the cycle-consistency generative adversarial network model to solve the image conversion problem and obtaining the result of FPGA routing congestion prediction includes:
step S401, a loss function of the cycle-consistency generative adversarial network is defined as:

$$ℒ ( {G}_{{img}_{p}} , {F}_{{img}_{rhm}} , {Dis}_{{img}_{rhm}} , {Dis}_{{img}_{p}} ) = {ℒ}_{g a n} ( {G}_{{img}_{p}} , {Dis}_{{img}_{rhm}} , {X}_{{img}_{p}} , {Y}_{{img}_{rhm}} ) + {ℒ}_{gan} ( {F}_{{img}_{rhm}} , {Dis}_{{img}_{p}} , {Y}_{{img}_{rhm}} , {X}_{{img}_{p}} ) + λ {ℒ}_{c y c} ( {G}_{{img}_{p}} , {F}_{{img}_{rhm}} ) + {γℒ}_{dis} ( {G}_{{img}_{p}} , {F}_{{img}_{rhm}} ) \qquad ( 1 )$$

wherein [symbol] _{gan}(G_{img}_{ₚ}, Dis_{img}_{ᵣₕₘ}, X_{img}_{ₚ}, Y_{img}_{ᵣₕₘ}) represents a forward loss function of the cycle-consistency generative adversarial network, the forward loss function is expressed as:

$${ℒ}_{gan} ( {G}_{{img}_{p}} , {Dis}_{{img}_{rhm}} , {X}_{{img}_{p}} , {Y}_{{img}_{rhm}} ) = \frac{1}{2} {E}_{{y}_{{img}_{rhm}} - {P}_{data} ( {Y}_{{img}_{rhm}} )} [ {( {Dis}_{{img}_{rhm}} ( {y}_{{img}_{rhm}} ) - 1 )}^{2} ] + \frac{1}{2} {E}_{{x}_{{img}_{p}} \sim {P}_{data} ( {X}_{{img}_{p}} )} [ {( {Dis}_{{img}_{rhm}} ( {G}_{{img}_{p}} ( {x}_{{img}_{p}} ) ) )}^{2} ] \qquad ( 2 )$$

wherein Dis_{img}_{ᵣₕₘ} represents a forward discriminate function of the cycle-consistency generative adversarial network, G_{img}_{ₚ} represents a forward generation function of the cycle-consistency generative adversarial network, x_{img}_{ₚ} ∈X_{img}_{ₚ} represents a set of samples of the image file imgₚ after placement, P_{data}(X_{img}_{ₚ}) represents a distribution function of a sample X_{img}_{ₚ}. E represents mathematical expectation, y_{img}_{ᵣₕₘ} ∈Y_{img}_{ᵣₕₘ} represents a set of samples of the heat map file imgᵣₕₘ, and P_{data}(Y_{img}_{ᵣₕₘ}) represents a distribution function of a sample Y_{img}_{ᵣₕₘ}.
[symbol] _{gan}(F_{img}_{ᵣₕₘ}, Dis_{img}_{ₚ}, Y_{img}_{ᵣₕₘ}, X_{img}_{ₚ}) represents a reverse loss function of the cycle-consistency generative adversarial network, the reverse loss function is expressed as:

$${ℒ}_{gan} ( {F}_{{img}_{rhm}} , {Dis}_{{img}_{p}} , {Y}_{{img}_{rhm}} , {X}_{{img}_{p}} ) = \frac{1}{2} {E}_{{x}_{{img}_{p}} \sim {P}_{data} ( {X}_{{img}_{p}} )} [ {( {Dis}_{{img}_{p}} ( {x}_{{img}_{p}} ) - 1 )}^{2} ] + \frac{1}{2} {E}_{{y}_{{img}_{rhm}} \sim {P}_{data} ( {Y}_{{img}_{rhm}} )} [ {( {Dis}_{{img}_{p}} ( {F}_{{img}_{rhm}} ( {y}_{{img}_{rhm}} ) ) )}^{2} ] \qquad ( 3 )$$

wherein F_{img}_{ᵣₕₘ} represents a reverse generation function of the cycle-consistency generative adversarial network, and Dis_{img}_{ₚ} represents a reverse discriminate function of the cycle-consistency generative adversarial network.

[symbol] _{cyc}(G_{img}_{ₚ}, F_{img}_{ᵣₕₘ}) represents consistency loss of the cycle-consistency generative adversarial network, the consistency loss is expressed as:

$${ℒ}_{c y c} ( {G}_{{img}_{p}} , {F}_{{img}_{rhm}} ) = {E}_{{y}_{{img}_{rhm}} ∼ {P}_{data} ( {Y}_{{img}_{rhm}} )} {‖ {G}_{{img}_{p}} ( {F}_{{img}_{rhm}} ( {y}_{{img}_{rhm}} ) ) - {y}_{{img}_{rhm}} ‖}_{1} + {E}_{{x}_{{img}_{p}} ∼ {p}_{data} ( {X}_{{img}_{p}} )} {‖ {F}_{{img}_{r h m}} ( {G}_{{img}_{p}} ( {x}_{i m {g}_{p}} ) ) - {x}_{{img}_{p}} ‖}_{1} \qquad ( 4 )$$

wherein [symbol] _{dis}(G_{img}_{ₚ}, F_{img}_{ᵣₕₘ}) represents a standard loss function of the cycle-consistency generative adversarial network, the standard loss function is expressed as:

$${ℒ}_{c y c} ( {G}_{{img}_{p}} , {F}_{{img}_{rhm}} ) = {E}_{{x}_{{img}_{rhm} , {y}_{{img}_{rhm}}} ∼ {P}_{data} ( {X}_{{img}_{p}} , {Y}_{{img}_{rhm}} )} {‖ {F}_{{img}_{rhm}} ( {y}_{{img}_{rhm}} ) - {x}_{{img}_{p}} ‖}_{1} + {E}_{{x}_{{img}_{p}} , {y}_{{img}_{rhm}} ∼ {p}_{data} ( {X}_{{img}_{p}} , {y}_{{img}_{rhm}} )} {‖ {G}_{{img}_{p}} ( {x}_{i m {g}_{p}} ) - {y}_{{img}_{rhm}} ‖}_{1} . \qquad ( 5 )$$

In the formula (1), λ and γ represent weight indicator factors, and both λ and γ are positive numbers.

Step S402, based on the definition, an objective function of the cycle-consistency generative adversarial network is represented as:

$${min}_{{G}_{{img}_{p}} , {F}_{{img}_{rhm}}} {min}_{{X}_{{img}_{p}} , {Y}_{{img}_{rhm}}} ℒ ( {G}_{{img}_{p}} , {F}_{{img}_{rhm}} , {Dis}_{{img}_{rhm}} , {Dis}_{{img}_{p}} ) . \qquad ( 6 )$$

Step S403, for the forward generation functions G_{img}_{ₚ} and the reverse generation function F_{img}_{ᵣₕₘ}, a first neural network model is constructed for training. The first neural network model specifically includes m₁ convolution modules, an intensive residual network composed of n₁ residual modules and m₁ deconvolution modules, and both m₁ and n₁ are positive integers.

Step S404, for the reverse discriminate functions Dis_{img}_{ₚ} and the forward discriminate function Dis_{img}_{ᵣₕₘ}, a second neural network model is constructed for training. The second neural network model includes m₂ convolution modules, and m₂ is a positive integer.

Step S405, multiple image files after placement imgₚ and multiple heat map files imgᵣₕₘ capable of representing the result of FPGA routing congestion are enabled to form an overall sample set.
dividing the overall sample set into two parts of a training sample set and a verification sample set
training the first neural network model and the second neural network model based on the training sample set, and in response to an objective function curve converges, completing the training to obtain an initial training model.
calibrating the initial training model by using the verification sample set to obtain a final training model.

Step S406, inputting the image file after placement imgₚ to the obtained final training model to obtain the result of routing congestion prediction.

Compared with the conventional art, the disclosure has the beneficial effects as follows.
(1) In the disclosure, the FPGA routing congestion prediction method and system are designed, so that the result of routing congestion can be accurately predicted based on the intermediate and result files produced in a placement stage, thus maintaining a great significance in reducing the time needed for routing iteration and further improving the working efficiency of an FPGA EDA tool, and strong support can be provided for a healthy and sustainable development of FPGA.
(2) Different from a common image conversion problem, the disclosure focuses on the change of the overall style of the image during FPGA placement and routing, can accurately reflect the change of characteristics before and after image conversion by extracting an effective feature information parameter, and can quickly solve the above problem without supervision by defining the cycle-consistency generative adversarial network model.

### BRIEF DESCRIPTION OF THE DRAWINGS

FIG. 1 is a schematic flowchart of an FPGA routing congestion prediction method according to the disclosure.

FIG. 2 is a schematic diagram of a manner of generating an image file after placement according to the disclosure.

FIG. 3 is a schematic structural diagram of a cycle-consistency generative adversarial network according to the disclosure.

FIG. 4 is a schematic structural diagram of an FPGA routing congestion system according to the disclosure.

### DETAILED DESCRIPTION OF THE EMBODIMENTS

The methods in the embodiments of the disclosure will be clearly and completely described below in combination with the drawings in the embodiments of the disclosure. It is apparent that the described embodiments are not all embodiments but part of embodiments of the disclosure. All other embodiments obtained by those of ordinary skill in the art on the basis of the embodiments in the disclosure without creative work shall fall within the scope of protection of the disclosure.

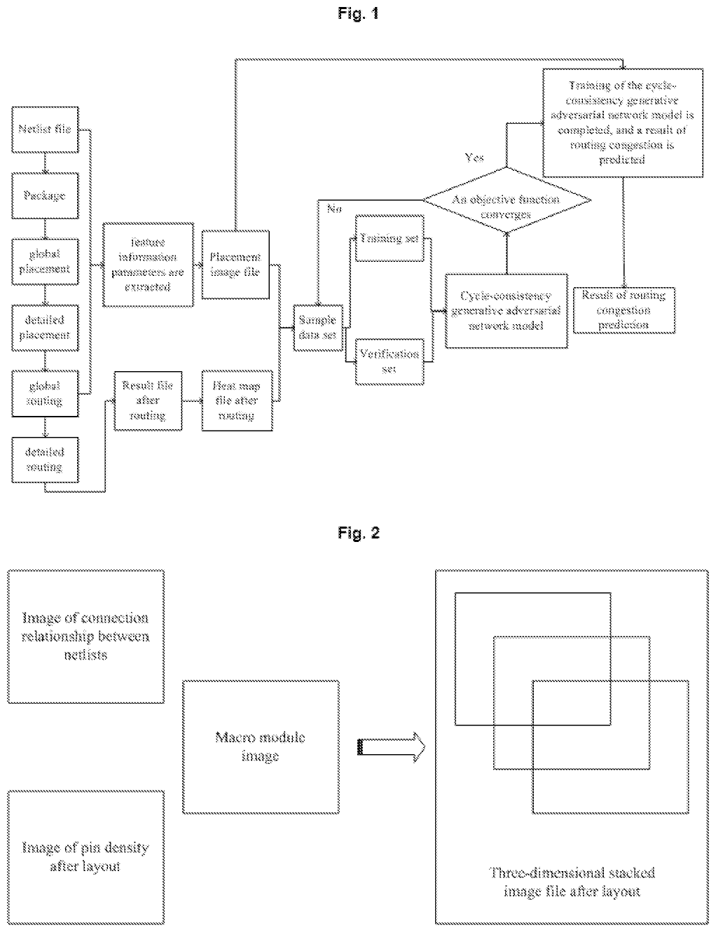

The embodiment of the disclosure provides an FPGA routing congestion prediction method, and the flow is shown in FIG. 1. The FPGA routing congestion prediction method includes:

At step S1, modeling an FPGA routing congestion prediction problem as an image conversion problem.

At step S2, extracting feature information parameters to obtain an image file after placement imgₚ.

At step S3, obtaining an image file after routing imgᵣ based on a routing result and converting the image file after routing imgᵣ into an image file capable of representing a result of FPGA routing congestion.

At step S4, defining a cycle-consistency generative adversarial network model to solve the image conversion problem, and a result of FPGA routing congestion prediction is obtained.

In step S1, based on result files after FPGA placement and routing, the image file after placement imgₚ and an image file after routing imgᵣ can be respectively obtained by the embodiment.

Both the image file after placement imgₚ and the image file after routing imgᵣ are the multi-channel images.

The image file after routing imgᵣ is transformed into a heat map imgᵣₕₘ, and the result of FPGA routing congestion is represented by the heat map imgᵣₕₘ.

There is a one-to-one mapping relationship between the image file after FPGA placement imgₚ and the heat map imgᵣₕₘ representing the result of FPGA routing congestion, and the solution of the heat map imgᵣₕₘ of the result of FPGA routing congestion is transformed into a process of generating the heat map imgᵣₕₘ of the result of FPGA routing congestion by using the known image file after FPGA placement imgₚ.

Further, in order to generate the required image file after placement imgₚ, it is necessary to extract the required feature information parameters. That is, in step S2, the feature information parameters are extracted to obtain the image file after placement imgₚ. In an embodiment, a complete placement and routing process is completed by using an automatic placement and routing tool, intermediate result information of each stage is saved, and the extraction of the feature information parameter is completed according to the saved intermediate result information.

In an embodiment, the feature information parameters include a connection relationship between netlists, pin density after placement and a macro module.

When an FPGA automatic routing tool executes a routing operation, the tool may automatically avoid a congestion area according to the congestion situation of a net under the guidance of the connection relationship between the netlists, so as to avoid the problem of scarce routing resources. Therefore, the embodiment takes the connection relationship between the netlists as the feature information parameter. In addition, after an FPGA automatic placement tool executes a placement operation, the pin density in each area of an FPGA chip can be calculated. In the area with high pin density in the chip, the net may be relatively dense, and the required routing resources may increase proportionally, which makes it more prone to routing congestion. Therefore, in the embodiment, the pin density after placement is used as the feature information parameters. After the FPGA automatic routing tool executes the routing operation, according to a conclusion of analysis after routing, it is to be concluded that a boundary area of the macro module and an adjacent area between two macro modules are prone to routing congestion. According to the above conclusion, the embodiment also takes the macro module as the feature information parameter.

According to the feature information parameters, feature images corresponding to each of the feature information parameters are generated. The feature images include an image of the connection relationship between the netlists, an image of the pin density after placement and a macro module image.

The generating the image file after placement imgₚ based on the image of the connection relationship between the netlists, the image of the pin density after placement and the macro module image includes:

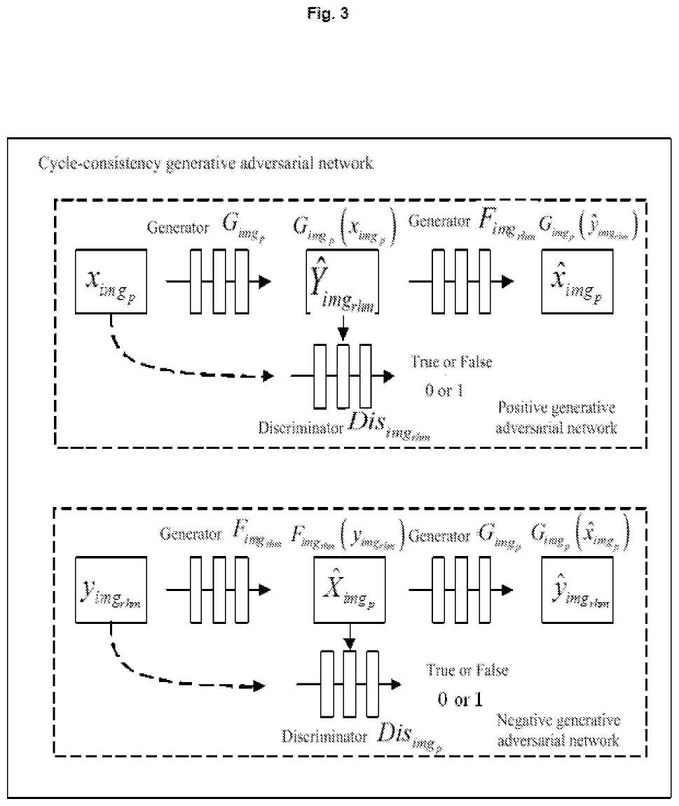

The image of the connection relationship between the netlists, the image of the pin density after placement and the macro module image are stacked to obtain the image file after placement imgₚ, which is shown in FIG. 2.

After the image file after placement is generated imgₚ, it is also necessary to obtain the heat map file imgᵣₕₘ capable of representing the result of FPGA routing congestion, that is, step S3, obtaining the image file after routing imgᵣ based on the routing result and converting the image file after routing imgᵣ into the heat map file imgᵣₕₘ capable of representing the result of FPGA routing congestion.

In an embodiment, a result file after routing is acquired.

The result file after routing is converted into the image file after routing imgᵣ.

The image file after routing imgᵣ is transformed into the heat map file imgᵣₕₘ to represent the result of FPGA routing congestion.

It is to be noted that, in order to solve the image conversion problem, it is necessary to construct the cycle-consistency generative adversarial network model to complete the solution of the image conversion problem, and the schematic diagram is shown in FIG. 3. The characteristic of the cycle-consistency generative adversarial network is that positive and negative generative adversarial networks are included to perform a cycle, so as to modify an output result of the model, which can prevent the feature of an image in a domain X_{img}_{ₚ} from being mapped to the same image in a domain Y_{img}_{ᵣₕₘ}. From the above description, it is to be concluded that two discriminate functions and two generation functions are respectively included in the cycle-consistency generative adversarial network.

In an embodiment, the step S4 is performed according to the following steps.

At step S401, a loss function of the cycle-consistency generative adversarial network is defined as:

$$ℒ ( {G}_{{img}_{p}} , {F}_{{img}_{rhm}} , {Dis}_{{img}_{rhm}} , {Dis}_{{img}_{p}} ) = {ℒ}_{g a n} ( {G}_{{img}_{p}} , {Dis}_{{img}_{rhm}} , {X}_{{img}_{p}} , {Y}_{{img}_{rhm}} ) + {ℒ}_{gan} ( {F}_{{img}_{rhm}} , {Dis}_{{img}_{p}} , {Y}_{{img}_{rhm}} , {X}_{{img}_{p}} ) + λ {ℒ}_{c y c} ( {G}_{{img}_{p}} , {F}_{{img}_{rhm}} ) + {γℒ}_{dis} ( {G}_{{img}_{p}} , {F}_{{img}_{rhm}} ) \qquad ( 1 )$$

wherein [symbol] _{gan}(G_{img}_{ₚ}, Dis_{img}_{ᵣₕₘ}, X_{img}_{ₚ}, Y_{img}_{ᵣₕₘ}) represents a forward loss function of the cycle-consistency generative adversarial network, the forward loss function is expressed as:

$${ℒ}_{gan} ( {G}_{{img}_{p}} , {Dis}_{{img}_{rhm}} , {X}_{{img}_{p}} , {Y}_{{img}_{rhm}} ) = \frac{1}{2} {E}_{{y}_{{img}_{rhm}} \sim {P}_{data} ( {Y}_{{img}_{rhm}} )} [ {( {Dis}_{{img}_{rhm}} ( {y}_{{img}_{rhm}} ) - 1 )}^{2} ] + \frac{1}{2} {E}_{{x}_{{img}_{p}} \sim {P}_{data} ( {X}_{{img}_{p}} )} [ {( {Dis}_{{img}_{rhm}} ( {G}_{{img}_{p}} ( {x}_{{img}_{p}} ) ) )}^{2} ] \qquad ( 2 )$$

wherein Dis_{img}_{ᵣₕₘ} represents a forward discriminate function of the cycle-consistency generative adversarial network, G_{img}_{ₚ} represents a forward generation function of the cycle-consistency generative adversarial network, x_{img}_{ₚ} ∈X_{img}_{ₚ} represents a set of samples of the image file imgₚ after placement, P_{data}(X_{img}_{ₚ}) represents a distribution function of a sample X_{img}_{ₚ}, E represents mathematical expectation, y_{img}_{ᵣₕₘ} ∈Y_{img}_{ᵣₕₘ} represents a set of samples of the heat map file imgᵣₕₘ, and P_{data}(Y_{img}_{ᵣₕₘ}) represents the distribution function of a sample Y_{img}_{ᵣₕₘ}.

Wherein [symbol] _{gan}(F_{img}_{ᵣₕₘ}, Dis_{img}_{ₚ}, Y_{img}_{ᵣₕₘ}, X_{img}_{ₚ}) represents a reverse loss function of the cycle-consistency generative adversarial network, the forward loss function is expressed as:

$${ℒ}_{gan} ( {F}_{{img}_{rhm}} , {Dis}_{{img}_{p}} , {Y}_{{img}_{rhm}} , {X}_{{img}_{p}} ) = \frac{1}{2} {E}_{{x}_{{img}_{p}} \sim {P}_{data} ( {X}_{{img}_{p}} )} [ {( {Dis}_{{img}_{p}} ( {x}_{{img}_{p}} ) - 1 )}^{2} ] + \frac{1}{2} {E}_{{y}_{{img}_{rhm}} \sim {P}_{data} ( {Y}_{{img}_{rhm}} )} [ {( {Dis}_{{img}_{p}} ( {F}_{{img}_{rhm}} ( {y}_{{img}_{rhm}} ) ) )}^{2} ] \qquad ( 3 )$$

wherein F_{img}_{ᵣₕₘ} represents a reverse generation function of the cycle-consistency generative adversarial network, and Dis_{img}_{ₚ} represents a reverse discriminate function of the cycle-consistency generative adversarial network.

[symbol] _{cyc}(G_{img}_{ₚ}, F_{img}_{ᵣₕₘ}) represents consistency loss of the cycle-consistency generative adversarial network, the consistency loss is expressed as:

$${ℒ}_{c y c} ( {G}_{{img}_{p}} , {F}_{{img}_{rhm}} ) = {E}_{{y}_{{img}_{rhm}} ∼ {P}_{data} ( {Y}_{{img}_{rhm}} )} {‖ {G}_{{img}_{p}} ( {F}_{{img}_{rhm}} ( {y}_{{img}_{rhm}} ) ) - {y}_{{img}_{rhm}} ‖}_{1} + {E}_{{x}_{{img}_{p}} ∼ {p}_{data} ( {X}_{{img}_{p}} )} {‖ {F}_{{img}_{r h m}} ( {G}_{{img}_{p}} ( {x}_{i m {g}_{p}} ) ) - {x}_{{img}_{p}} ‖}_{1} \qquad ( 4 )$$

where [symbol] _{dis}(G_{img}_{ₚ}, F_{img}_{ᵣₕₘ}) represents a standard loss function of the cycle-consistency generative adversarial network, the standard loss function is expressed as:

$${ℒ}_{c y c} ( {G}_{{img}_{p}} , {F}_{{img}_{rhm}} ) = {E}_{{x}_{{img}_{rhm} , {y}_{{img}_{rhm}}} ∼ {P}_{data} ( {X}_{{img}_{p}} , {Y}_{{img}_{rhm}} )} {‖ {F}_{{img}_{rhm}} ( {y}_{{img}_{rhm}} ) - {x}_{{img}_{p}} ‖}_{1} + {E}_{{x}_{{img}_{p}} , {y}_{{img}_{rhm}} ∼ {p}_{data} ( {X}_{{img}_{p}} , {y}_{{img}_{rhm}} )} {‖ {G}_{{img}_{p}} ( {x}_{i m {g}_{p}} ) - {y}_{{img}_{rhm}} ‖}_{1} . \qquad ( 5 )$$

In the formula (1), λ and γ represent weight indicator factors, and both λ and γ are positive numbers.

At step S402, according to the definition, an objective function of the cycle-consistency generative adversarial network is represented as:

$${min}_{{G}_{{img}_{p}} , {F}_{{img}_{rhm}}} {min}_{{X}_{{img}_{p}} , {Y}_{{img}_{rhm}}} ℒ ( {G}_{{img}_{p}} , {F}_{{img}_{rhm}} , {Dis}_{{img}_{rhm}} , {Dis}_{{img}_{p}} ) . \qquad ( 6 )$$

At step S403, for the forward generation functions G_{img}_{ₚ} and the reverse generation function F_{img}_{ᵣₕₘ}, a first neural network model is constructed for training. The first neural network model has a dumbbell-shaped symmetrical structure, which is as follows.

The first neural network model includes m₁ convolution modules, an intensive residual network composed of n₁ residual modules and m₁ deconvolution modules, and both m₁ and n₁ are positive integers.

In an embodiment, a concrete form of the first neural network model is that five convolution modules, an intensive residual network composed of nine residual modules and five deconvolution modules are provided, that is, m₁=5, and m₁=9.

At step S404, for the reverse discriminate functions Dis_{img}_{ₚ} and the forward discriminate function Dis_{img}_{ᵣₕₘ}, a second neural network model is constructed for training. The second neural network model includes m₂ convolution modules, and m₂ is a positive integer.

In an embodiment, the concrete form of the second neural network model is a convolutional neural network provided with five convolution modules, that is, m₂=5.

At step S405, multiple image files after placement imgₚ and multiple heat map files imgᵣₕₘ capable of representing the result of FPGA routing congestion are enabled to form an overall sample set.

Further, the overall sample set is divided into two parts of a training sample set and a verification sample set.

In an embodiment, the training sample set includes b₁ image files after placement imgₚ and c₁ heat map files imgᵣₕₘ capable of representing the result of FPGA routing congestion.

The verification sample set includes b₂ image files after placement imgₚ and c₂ heat map files imgᵣₕₘ capable of representing the result of FPGA routing congestion.

It is to be noted that parameters b₁, b₂, c₁ and c₂ need to meet the following conditions:

$${b}_{1} + {b}_{2} = N \qquad ( 7 )$$

$${c}_{1} + {c}_{2} = M \qquad ( 8 )$$

wherein N represents the number of image files after placement imgₚ in the overall sample set, and M represents the number of heat map files imgᵣₕₘ in the overall sample set.

The first neural network model and the second neural network model are trained according to the training sample set, and the training is completed when an objective function curve converges to obtain an initial training model.

Further, the initial training model is calibrated by using the verification sample set to obtain a final training model.

At step S406, the image file after placement imgₚ is input to the obtained final training model to obtain the result of routing congestion prediction.

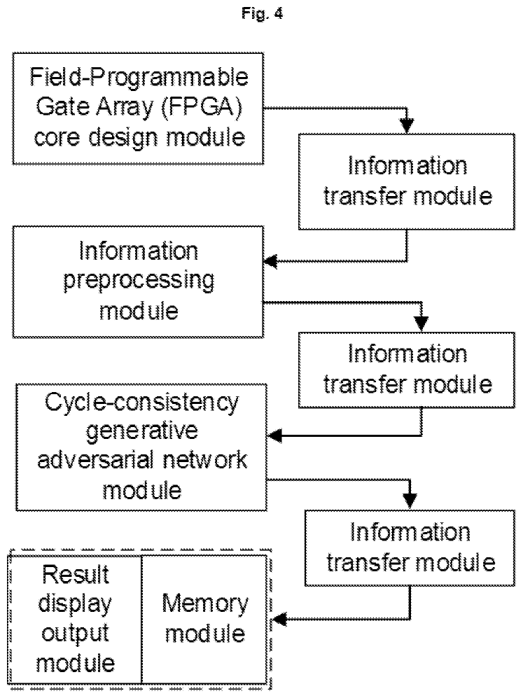

The disclosure further provides an FPGA routing congestion prediction system shown in FIG. 4, which includes: an FPGA core design module, an information preprocessing module and a cycle-consistency generative adversarial network module.

The FPGA core design module is configured to model an FPGA routing congestion prediction problem as an image conversion problem and complete modeling of FPGA routing congestion prediction.

It is to be noted that a placement and routing tool is executed in the FPGA core design module.

The information preprocessing module is configured to extract required feature information parameters to obtain an image file after placement imgₚ and an image file after routing imgᵣ.

It is to be noted that S2 and S3 are executed in the information preprocessing module.

The cycle-consistency generative adversarial network module is configured to define a cycle-consistency generative adversarial network model to solve the image conversion problem, and obtain a result of FPGA routing congestion prediction.

It is to be noted that S4 is executed in the cycle-consistency generative adversarial network module.

In an embodiment of the disclosure, a memory module shall also be included, which is configured to store a series of intermediate and result files and a result file of routing congestion prediction.

In an embodiment of the disclosure, a display module shall also be included, which is configured to display the result of routing congestion prediction.

In an embodiment of the disclosure, an information transfer module shall also be included, which is configured to transfer information among the modules.

In an embodiment, the operation modeling the FPGA routing congestion prediction problem into the image conversion problem in the FPGA core design module is as follows.

According to result files after FPGA placement and routing, an image file after FPGA placement imgₚ and an image file after FPGA routing imgᵣ are respectively obtained; and the image file after FPGA placement imgₚ and the image file after FPGA routing imgᵣ are the multi-channel images.

The image file after FPGA routing imgᵣ is transformed into a heat map imgᵣₕₘ, and the result of FPGA routing congestion is represented by the heat map imgᵣₕₘ.

There is a one-to-one mapping relationship between the image file after FPGA placement imgₚ and the heat map imgᵣₕₘ representing the result of FPGA routing congestion, and the solution of the heat map imgᵣₕₘ of the result of FPGA routing congestion is transformed into a process of generating the heat map imgᵣₕₘ of the result of FPGA routing congestion by using the known image file after FPGA placement imgₚ, that is, completing the modeling of the FPGA routing congestion prediction problem.

In an embodiment extracting the feature information parameters to obtain the image file after placement imgₚ in the information preprocessing module includes the following operations.

The feature information parameters include a connection relationship between netlists, pin density after placement and a macro module.

According to the feature information parameters, feature images corresponding to each of the feature information parameters are generated. The feature images include an image of the connection relationship between the netlists, an image of the pin density after placement and a macro module image.

The operation of generating the image file after placement imgₚ based on the feature images includes the following operations.

The image of the connection relationship between the netlists, the image of the pin density after placement and the macro module image are stacked to obtain the image file after placement imgₚ.

The operation of obtaining the image file after routing imgᵣ based on a routing result and converting the image file after routing imgᵣ into an image file capable of representing the result of FPGA routing congestion includes the following operations.

A result file after routing is acquired.

The result file after routing is converted into the image file after routing imgᵣ.

The image file after routing imgᵣ is transformed into the heat map file imgᵣₕₘ to represent the result of FPGA routing congestion.

In an embodiment, the cycle-consistency generative adversarial network module is configured to define the cycle-consistency generative adversarial network model to solve the image conversion problem, and obtain the result of FPGA routing congestion prediction, which includes the following operations.

At step S401, a loss function of the cycle-consistency generative adversarial network is defined as:

$$ℒ ( {G}_{{img}_{p}} , {F}_{{img}_{rhm}} , {Dis}_{{img}_{rhm}} , {Dis}_{{img}_{p}} ) = {ℒ}_{g a n} ( {G}_{{img}_{p}} , {Dis}_{{img}_{rhm}} , {X}_{{img}_{p}} , {Y}_{{img}_{rhm}} ) + {ℒ}_{gan} ( {F}_{{img}_{rhm}} , {Dis}_{{img}_{p}} , {Y}_{{img}_{rhm}} , {X}_{{img}_{p}} ) + λ {ℒ}_{c y c} ( {G}_{{img}_{p}} , {F}_{{img}_{rhm}} ) + {γℒ}_{dis} ( {G}_{{img}_{p}} , {F}_{{img}_{rhm}} ) \qquad ( 1 )$$

where [symbol] _{gan}(G_{img}_{ₚ}, Dis_{img}_{ᵣₕₘ}, X_{img}_{ₚ}, Y_{img}_{ᵣₕₘ}) represents a forward loss function of the cycle-consistency generative adversarial network, the forward loss function is expressed as:

$${ℒ}_{gan} ( {G}_{{img}_{p}} , {Dis}_{{img}_{rhm}} , {X}_{{img}_{p}} , {Y}_{{img}_{rhm}} ) = \frac{1}{2} {E}_{{y}_{{img}_{rhm}} \sim {P}_{data} ( {Y}_{{img}_{rhm}} )} [ {( {Dis}_{{img}_{rhm}} ( {y}_{{img}_{rhm}} ) - 1 )}^{2} ] + \frac{1}{2} {E}_{{x}_{{img}_{p}} \sim {P}_{data} ( {X}_{{img}_{p}} )} [ {( {Dis}_{{img}_{rhm}} ( {G}_{{img}_{p}} ( {x}_{{img}_{p}} ) ) )}^{2} ] \qquad ( 2 )$$

wherein Dis_{img}_{ᵣₕₘ} represents a forward discriminate function of the cycle-consistency generative adversarial network, G_{img}_{ₚ} represents a forward generation function of the cycle-consistency generative adversarial network, x_{img}_{ₚ} ∈X_{img}_{ₚ} represents a set of samples of the image file imgₚ after placement, P_{data}(X_{img}_{ₚ}) represents a distribution function of a sample X_{img}_{ₚ}, E represents mathematical expectation, y_{img}_{ᵣₕₘ} ∈Y_{img}_{ᵣₕₘ} representing a set of samples of the heat map file imgᵣₕₘ, and P_{data}(Y_{img}_{ᵣₕₘ}) represents a distribution function of a sample Y_{img}_{ᵣₕₘ}. [symbol] _{gan}(F_{img}_{ᵣₕₘ}, Dis_{img}_{ₚ}, Y_{img}_{ᵣₕₘ}, X_{img}_{ₚ}) represents a reverse loss function of the cycle-consistency generative adversarial network, the reverse loss function is expressed as:

$${ℒ}_{gan} ( {F}_{{img}_{rhm}} , {Dis}_{{img}_{p}} , {Y}_{{img}_{rhm}} , {X}_{{img}_{p}} ) = \frac{1}{2} {E}_{{x}_{{img}_{p}} \sim {P}_{data} ( {X}_{{img}_{p}} )} [ {( {Dis}_{{img}_{p}} ( {x}_{{img}_{p}} ) - 1 )}^{2} ] + \frac{1}{2} {E}_{{y}_{{img}_{rhm}} \sim {P}_{data} ( {Y}_{{img}_{rhm}} )} [ {( {Dis}_{{img}_{p}} ( {F}_{{img}_{rhm}} ( {y}_{{img}_{rhm}} ) ) )}^{2} ] \qquad ( 3 )$$

wherein F_{img}_{ᵣₕₘ} represents a reverse generation function of the cycle-consistency generative adversarial network, and Dis_{img}_{ₚ} represents a reverse discriminate function of the cycle-consistency generative adversarial network.

[symbol] _{cyc}(G_{img}_{ₚ}, F_{img}_{ᵣₕₘ}) represents consistency loss of the cycle-consistency generative) adversarial network, the consistency loss is expressed as:)

$${ℒ}_{c y c} ( {G}_{{img}_{p}} , {F}_{{img}_{rhm}} ) = {E}_{{y}_{{img}_{rhm}} ∼ {P}_{data} ( {Y}_{{img}_{rhm}} )} {‖ {G}_{{img}_{p}} ( {F}_{{img}_{rhm}} ( {y}_{{img}_{rhm}} ) ) - {y}_{{img}_{rhm}} ‖}_{1} + {E}_{{x}_{{img}_{p}} ∼ {p}_{data} ( {X}_{{img}_{p}} )} {‖ {F}_{{img}_{r h m}} ( {G}_{{img}_{p}} ( {x}_{i m {g}_{p}} ) ) - {x}_{{img}_{p}} ‖}_{1} \qquad ( 4 )$$

wherein [symbol] _{dis}(G_{img}_{ₚ}, F_{img}_{ᵣₕₘ}) represents a standard loss function of the cycle-consistency generative adversarial network, the standard loss function is expressed as:

$${ℒ}_{c y c} ( {G}_{{img}_{p}} , {F}_{{img}_{rhm}} ) = {E}_{{x}_{{img}_{rhm} , {y}_{{img}_{rhm}}} ∼ {P}_{data} ( {X}_{{img}_{p}} , {Y}_{{img}_{rhm}} )} {‖ {F}_{{img}_{rhm}} ( {y}_{{img}_{rhm}} ) - {x}_{{img}_{p}} ‖}_{1} + {E}_{{x}_{{img}_{p}} , {y}_{{img}_{rhm}} ∼ {p}_{data} ( {X}_{{img}_{p}} , {y}_{{img}_{rhm}} )} {‖ {G}_{{img}_{p}} ( {x}_{i m {g}_{p}} ) - {y}_{{img}_{rhm}} ‖}_{1} . \qquad ( 5 )$$

In the formula (1), λ and γ represent weight indicator factors, and both λ and γ are positive numbers.

At step S402, representing, based on the definition, an objective function of the cycle-consistency generative adversarial network as:

$${min}_{{G}_{{img}_{p}} , {F}_{{img}_{rhm}}} {min}_{{X}_{{img}_{p}} , {Y}_{{img}_{rhm}}} ℒ ( {G}_{{img}_{p}} , {F}_{{img}_{rhm}} , {Dis}_{{img}_{rhm}} , {Dis}_{{img}_{p}} ) . \qquad ( 6 )$$

At step S403, for the forward generation functions G_{img}_{ₚ} and the reverse generation function F_{img}_{ᵣₕₘ}, a first neural network model is constructed for training. The first neural network model has a dumbbell-shaped symmetrical structure.

In an embodiment, the first neural network model includes m₁ convolution modules, an intensive residual network composed of n₁ residual modules and m₁ deconvolution modules, and both m₁ and n₁ are positive integers.

At step S404, for the reverse discriminate functions Dis_{img}_{ₚ} and the forward discriminate function Dis_{img}_{ᵣₕₘ}, a second neural network model is constructed for training. The second neural network model includes m₂ convolution modules, and m₂ is a positive integer.

At step S405, multiple image files after placement imgₚ and multiple heat map files imgᵣₕₘ capable of representing the result of FPGA routing congestion are enabled to form an overall sample set.

Further, the overall sample set is divided into two parts of a training sample set and a verification sample set.

Further, the first neural network model and the second neural network model are trained according to the training sample set, and the training is completed when an objective function curve converges to obtain an initial training model.

Further, the initial training model is calibrated by using the verification sample set to obtain a final training model.

At step S406, the image file after placement imgₚ is input to the obtained final training model to obtain the result of routing congestion prediction.

Through the above embodiment, the disclosure can accurately predict congestion information in a routing stage according to a series of parameters obtained in a placement stage, adaptively adjust the operation strategy of the FPGA placement and routing method according to the obtained routing congestion information, guide the optimization of the FPGA placement and routing process, and improve the operation efficiency of the FPGA placement and routing tool by more than 10%.

The embodiments in the specification are described in a related manner. The same or similar parts between the embodiments can be referred to each other, and each embodiment focuses on the differences from other embodiments. In particular, for the system embodiment, since it is basically similar to the method embodiment, the description is relatively simple, and the relevant part can be referred to the description of the method embodiment.

The above are only the preferred embodiments of the disclosure and are not intended to limit the scope of protection of the disclosure. Any modifications, equivalent replacements, improvements and the like made within the spirit and principle of the disclosure shall fall within the scope of protection of the disclosure.

1. A Field-Programmable Gate Array (FPGA) routing congestion prediction method, comprising:
step S1: modeling FPGA routing congestion prediction: modeling an FPGA routing congestion prediction problem as an image conversion problem;
step S2: extracting feature information parameters to obtain an image file after placement imgₚ;
step S3: obtaining an image file after routing imgᵣ based on a routing result, and converting the image file after routing imgᵣ into a heat map file imgᵣₕₘ capable of representing a result of FPGA routing congestion;
step S4: defining a cycle-consistency generative adversarial network model to solve the image conversion problem, and obtaining a result of FPGA routing congestion prediction.

2. The FPGA routing congestion prediction method as claimed in claim 1, wherein the step S1, modeling the FPGA routing congestion prediction problem into the image conversion problem comprises:
obtaining an image file after FPGA placement imgₚ based on a result file of FPGA placement;
obtaining an image file after FPGA routing imgᵣ based on a result file after FPGA routing;
wherein the image file after FPGA placement imgₚ and the image file after FPGA routing imgᵣ are multi-channel images:
transforming the image file after FPGA routing imgᵣ into a heat map imgᵣₕₘ, and representing a result of FPGA routing congestion by the heat map imgᵣₕₘ;
wherein there is a one-to-one mapping relationship between the image file after FPGA placement imgₚ and the heat map imgᵣₕₘ representing the result of FPGA routing congestion, the solution of the heat map imgᵣₕₘ being transformed into a process of generating the heat map imgᵣₕₘ representing the result of FPGA routing congestion by using the known image file after FPGA placement imgₚ, that is, completing the modeling of the FPGA routing congestion prediction problem.

3. The FPGA routing congestion prediction method as claimed in claim 1, wherein the step S2, extracting the feature information parameters to obtain the image file after placement imgₚ comprises:
the feature information parameters comprise a connection relationship between netlists, pin density after placement and a macro module; and
generating feature images corresponding to each feature information parameter based on the feature information parameters, wherein the feature images comprise an image of the connection relationship between the netlists, an image of the pin density after placement and a macro module image;
wherein generating the image file after placement imgₚ based on the feature images comprises:
stacking the image of the connection relationship between the netlists, the image of the pin density after placement and the macro module image to obtain the image file after placement imgₚ.

4. The FPGA routing congestion prediction method as claimed in claim 1, wherein the step S3, obtaining the image file after routing imgᵣ based on the routing result, and converting the image file after routing imgᵣ into the heat map file imgᵣₕₘ capable of representing the result of FPGA routing congestion comprises:
acquiring a result file after routing;
converting the result file after routing into an image file after routing imgᵣ;
transforming the image file after routing imgᵣ into the heat map file imgᵣₕₘ to represent the result of FPGA routing congestion.

5. The FPGA routing congestion prediction method as claimed in claim 1, wherein the step S4, defining the cycle-consistency generative adversarial network model to solve the image conversion problem, and obtaining the result of FPGA routing congestion prediction comprises:
step S401: defining a loss function of the cycle-consistency generative adversarial network as:
$$ℒ ( G \text{?} , F \text{?} , Dis \text{?} , Dis \text{?} ) = ℒ \text{?} ( G \text{?} , Dis \text{?} , X \text{?} , Y \text{?} ) + ℒ \text{?} ( F \text{?} , Dis \text{?} , Y \text{?} , X \text{?} ) + λℒ \text{?} ( G \text{?} , F \text{?} ) + γℒ \text{?} ( G \text{?} , F \text{?} ) \qquad ( 1 )$$
$$\text{?} \text{indicates text missing or illegible when filed}$$
wherein [symbol] _{gan}(G_{img}_{ₚ}, Dis_{img}_{ᵣₕₘ}, X_{img}_{ₚ}, Y_{img}_{ᵣₕₘ}) represents a forward loss function of the cycle-consistency generative adversarial network, the forward loss function is expressed as:
$${ℒ}_{gan} ( {G}_{{img}_{p}} , {Dis}_{{img}_{rhm}} , {X}_{{img}_{p}} , {Y}_{{img}_{rhm}} ) = \frac{1}{2} {E}_{{y}_{{img}_{rhm}} \sim {P}_{data} ( {Y}_{{img}_{rhm}} )} [ {( {Dis}_{{img}_{rhm}} ( {y}_{{img}_{rhm}} ) - 1 )}^{2} ] + \frac{1}{2} {E}_{{x}_{{img}_{p}} \sim {P}_{data} ( {X}_{{img}_{p}} )} [ {( {Dis}_{{img}_{rhm}} ( {G}_{{img}_{p}} ( {x}_{{img}_{p}} ) ) )}^{2} ] \qquad ( 2 )$$
wherein Dis_{img}_{ᵣₕₘ} represents a forward discriminate function of the cycle-consistency generative adversarial network, G_{img}_{ₚ} represents a forward generation function of the cycle-consistency generative adversarial network, x_{img}_{ₚ} ∈X_{img}_{ₚ} represents a set of samples of the image file imgₚ after placement, P_{data}(X_{img}_{ₚ}) representing a distribution function of a sample X_{img}_{ₚ}, E represents a mathematical expectation, y_{img}_{ᵣₕₘ} ∈Y_{img}_{ᵣₕₘ} represents a set of samples of the heat map file imgᵣₕₘ, and P_{data}(Y_{img}_{ᵣₕₘ}) represents a distribution function of a sample Y_{img}_{ᵣₕₘ}; and [symbol]
_{gan}(F_{img}_{ᵣₕₘ}, Dis_{img}_{ₚ}, Y_{img}_{ᵣₕₘ}, X_{img}_{ₚ}) represents a reverse loss function of the cycle-consistency generative adversarial network, the reverse loss function is expressed as:
$${ℒ}_{gan} ( {F}_{{img}_{rhm}} , {Dis}_{{img}_{p}} , {Y}_{{img}_{rhm}} , {X}_{{img}_{p}} ) = \frac{1}{2} {E}_{{x}_{{img}_{p}} \sim {P}_{data} ( {X}_{{img}_{p}} )} [ {( {Dis}_{{img}_{p}} ( {x}_{{img}_{p}} ) - 1 )}^{2} ] + \frac{1}{2} {E}_{{y}_{{img}_{rhm}} \sim {P}_{data} ( {Y}_{{img}_{rhm}} )} [ {( {Dis}_{{img}_{p}} ( {F}_{{img}_{rhm}} ( {y}_{{img}_{rhm}} ) ) )}^{2} ] \qquad ( 3 )$$
wherein F_{img}_{ᵣₕₘ} represents a reverse generation function of the cycle-consistency generative adversarial network, Dis_{img}_{ₚ} represents a reverse discriminate function of the cycle-consistency generative adversarial network; and [symbol]
_{cyc}(G_{img}_{ₚ}, F_{img}_{ᵣₕₘ}) represents consistency loss of the cycle-consistency generative adversarial network, the consistency loss is expressed as:
$${ℒ}_{c y c} ( {G}_{{img}_{p}} , {F}_{{img}_{rhm}} ) = {E}_{{y}_{{img}_{rhm}} ∼ {P}_{data} ( {Y}_{{img}_{rhm}} )} {‖ {G}_{{img}_{p}} ( {F}_{{img}_{rhm}} ( {y}_{{img}_{rhm}} ) ) - {y}_{{img}_{rhm}} ‖}_{1} + {E}_{{x}_{{img}_{p}} ∼ {p}_{data} ( {X}_{{img}_{p}} )} {‖ {F}_{{img}_{r h m}} ( {G}_{{img}_{p}} ( {x}_{i m {g}_{p}} ) ) - {x}_{{img}_{p}} ‖}_{1} \qquad ( 4 )$$
wherein [symbol] _{dis}(G_{img}_{ₚ}, F_{img}_{ᵣₕₘ}) represents a standard loss function of the cycle-consistency generative adversarial network, the standard loss function is expressed as:
$${ℒ}_{c y c} ( {G}_{{img}_{p}} , {F}_{{img}_{rhm}} ) = {E}_{{x}_{{img}_{rhm} , {y}_{{img}_{rhm}}} ∼ {P}_{data} ( {X}_{{img}_{p}} , {Y}_{{img}_{rhm}} )} {‖ {F}_{{img}_{rhm}} ( {y}_{{img}_{rhm}} ) - {x}_{{img}_{p}} ‖}_{1} + {E}_{{x}_{{img}_{p}} , {y}_{{img}_{rhm}} ∼ {p}_{data} ( {X}_{{img}_{p}} , {y}_{{img}_{rhm}} )} {‖ {G}_{{img}_{p}} ( {x}_{i m {g}_{p}} ) - {y}_{{img}_{rhm}} ‖}_{1} \qquad ( 5 )$$
in the formula (1), λ and γ represent weight indicator factors, both λ and γ are positive numbers;
step S402: representing, based on the definition, an objective function of the cycle-consistency generative adversarial network as:
$${min}_{{G}_{{img}_{p}} , {F}_{{img}_{rhm}}} {min}_{{X}_{{img}_{p}} , {Y}_{{img}_{rhm}}} ℒ ( {G}_{{img}_{p}} , {F}_{{img}_{rhm}} , {Dis}_{{img}_{rhm}} , {Dis}_{{img}_{p}} ) ; \qquad ( 6 )$$
step S403: for the forward generation function G_{img}_{ₚ} and the reverse generation function F_{img}_{ᵣₕₘ}, constructing a first neural network model for training, the first neural network model comprises m₁ convolution modules, an intensive residual network composed of n₁ residual modules and m₁ deconvolution modules, both m₁ and n₁ being positive integers;
step S404: for the reverse discriminate function Dis_{img}_{ₚ} and the forward discriminate function Dis_{img}_{ᵣₕₘ}, constructing a second neural network model for training, the second neural network model comprises m₂ convolution modules, m₂ being a positive integer;
step S405: enabling multiple image files after placement imgₚ and multiple heat map files imgᵣₕₘ capable of representing the result of FPGA routing congestion to form an overall sample set:
a). dividing the overall sample set into two parts of a training sample set and a verification sample set:
b). training the first neural network model and the second neural network model based on the training sample set, and in response to an objective function curve converges, completing the training to obtain an initial training model;
c). calibrating the initial training model by using the verification sample set to obtain a final training model; and
step S406: inputting the image file after placement imgₚ into the final training model to obtain the result of routing congestion prediction.

6. A Field-Programmable Gate Array (FPGA) routing congestion prediction system, comprising:
an FPGA core design module, configured to model an FPGA routing congestion prediction problem as an image conversion problem and complete modeling of FPGA routing congestion prediction;
an information preprocessing module, configured to extract required feature information parameters to obtain an image file after placement imgₚ and an image file after routing imgᵣ;
a cycle-consistency generative adversarial network module, configured to define a cycle-consistency generative adversarial network model to solve the image conversion problem, and obtain a result of FPGA routing congestion prediction.

7. The FPGA routing congestion prediction system as claimed in claim 6. further comprising a memory module, a display module and an information transfer module, the memory module is configured to store an intermediate file and a result file of routing congestion prediction, the display module is configured to display the result of routing congestion prediction, and the information transfer module is configured to transfer information among the memory module, the display module and information transfer module.

8. The FPGA routing congestion prediction system as claimed in claim 6, wherein transforming the FPGA routing congestion prediction problem into the image conversion problem comprises:
obtaining an image file after FPGA placement imgₚ based on a result file of FPGA placement;
obtaining an image file after FPGA routing imgᵣ based on a result file after FPGA routing;
wherein the image file after FPGA placement imgₚ and the image file after FPGA routing imgᵣ are multi-channel images;
transforming the image file after FPGA routing imgᵣ into a heat map imgᵣₕₘ, and representing a result of FPGA routing congestion by the heat map imgᵣₕₘ;
wherein there is a one-to-one mapping relationship between the image file after FPGA placement imgₚ and the heat map imgᵣₕₘ representing the result of FPGA routing congestion, the solution of the heat map imgᵣₕₘ of the result of FPGA routing congestion being transformed into a process of generating the heat map imgᵣₕₘ of the result of FPGA routing congestion by using the known image file after FPGA placement imgₚ, that is, completing the modeling of the FPGA routing congestion prediction problem.

9. The FPGA routing congestion prediction system as claimed in claim 6, wherein extracting the feature information parameters to obtain the image file after placement imgₚ comprises:
the feature information parameters comprise a connection relationship between netlists, pin density after placement and a macro module; and
generating feature images corresponding to each feature information parameter based on the feature information parameters, wherein the feature images comprise an image of the connection relationship between the netlists, an image of the pin density after placement and a macro module image;
wherein generating the image file after placement imgₚ based on the feature images comprises:
stacking the image of the connection relationship between the netlists, the image of the pin density after placement and the macro module image to obtain the image file after placement imgₚ;
wherein obtaining the image file after routing imgᵣ based on the routing result, and converting the image file after routing imgᵣ into the heat map file imgᵣₕₘ capable of representing the result of FPGA routing congestion comprises:
acquiring a result file after routing;
converting the result file after routing into the image file imgᵣ after routing; and
transforming the image file after routing imgᵣ into a heat map file imgᵣₕₘ to represent the result of FPGA routing congestion.

10. The FPGA routing congestion prediction system as claimed in claim 6, wherein
defining the cycle-consistency generative adversarial network model to solve the image conversion problem and obtaining the result of FPGA routing congestion prediction comprises:
step S401: defining a loss function of the cycle-consistency generative adversarial network as:
$$ℒ ( {G}_{{img}_{p}} , {F}_{{img}_{rhm}} , {Dis}_{{img}_{rhm}} , {Dis}_{{img}_{p}} ) = {ℒ}_{g a n} ( {G}_{{img}_{p}} , {Dis}_{{img}_{rhm}} , {X}_{{img}_{p}} , {Y}_{{img}_{rhm}} ) + {ℒ}_{gan} ( {F}_{{img}_{rhm}} , {Dis}_{{img}_{p}} , {Y}_{{img}_{rhm}} , {X}_{{img}_{p}} ) + λ {ℒ}_{c y c} ( {G}_{{img}_{p}} , {F}_{{img}_{rhm}} ) + {γℒ}_{dis} ( {G}_{{img}_{p}} , {F}_{{img}_{rhm}} ) \qquad ( 1 )$$
wherein [symbol] _{gan}(G_{img}_{ₚ}, Dis_{img}_{ᵣₕₘ}, X_{img}_{ₚ}, Y_{img}_{ᵣₕₘ}) represents a forward loss function of the cycle-consistency generative adversarial network, the forward loss function is expressed as:
$${ℒ}_{gan} ( {G}_{{img}_{p}} , {Dis}_{{img}_{rhm}} , {X}_{{img}_{p}} , {Y}_{{img}_{rhm}} ) = \frac{1}{2} {E}_{{y}_{{img}_{rhm}} \sim {P}_{data} ( {Y}_{{img}_{rhm}} )} [ {( {Dis}_{{img}_{rhm}} ( {y}_{{img}_{rhm}} ) - 1 )}^{2} ] + \frac{1}{2} {E}_{{x}_{{img}_{p}} \sim {P}_{data} ( {X}_{{img}_{p}} )} [ {( {Dis}_{{img}_{rhm}} ( {G}_{{img}_{p}} ( {x}_{{img}_{p}} ) ) )}^{2} ] \qquad ( 2 )$$
wherein Dis_{img}_{ᵣₕₘ} represents a forward discriminate function of the cycle-consistency generative adversarial network, G_{img}_{ₚ} represents a forward generation function of the cycle-consistency generative adversarial network, x_{img}_{ₚ} ∈X_{img}_{ₚ} represents a set of samples of the image file imgₚ after placement, P_{data}(X_{img}_{ₚ}) represents a distribution function of a sample X_{img}_{ₚ}, E represents a mathematical expectation, y_{img}_{ᵣₕₘ} ∈Y_{img}_{ᵣₕₘ} represents a set of samples of the heat map file imgᵣₕₘ, and P_{data}(Y_{img}_{ᵣₕₘ}) represents a distribution function of a sample Y_{img}_{ᵣₕₘ}; and [symbol]
_{gan}(F_{img}_{ᵣₕₘ}, Dis_{img}_{ₚ}, Y_{img}_{ᵣₕₘ}, X_{img}_{ₚ}) represents a reverse loss function of the cycle-consistency generative adversarial network, the reverse loss function is expressed as:
$${ℒ}_{gan} ( {F}_{{img}_{rhm}} , {Dis}_{{img}_{p}} , {Y}_{{img}_{rhm}} , {X}_{{img}_{p}} ) = \frac{1}{2} {E}_{{x}_{{img}_{p}} \sim {P}_{data} ( {X}_{{img}_{p}} )} [ {( {Dis}_{{img}_{p}} ( {x}_{{img}_{p}} ) - 1 )}^{2} ] + \frac{1}{2} {E}_{{y}_{{img}_{rhms}} \sim {P}_{data} ( {Y}_{{img}_{rhm}} )} [ {( {Dis}_{{img}_{p}} ( {F}_{{img}_{rhm}} ( {y}_{{img}_{rhm}} ) ) )}^{2} ] \qquad ( 3 )$$
wherein F_{img}_{ᵣₕₘ} represents a reverse generation function of the cycle-consistency generative adversarial network, Dis_{img}_{ₚ} represents a reverse discriminate function of the cycle-consistency generative adversarial network; and [symbol]
_{cyc}(G_{img}_{ₚ}, F_{img}_{ᵣₕₘ}) represents consistency loss of the cycle-consistency generative adversarial network, the consistency loss is expressed as:
$${ℒ}_{c y c} ( {G}_{{img}_{p}} , {F}_{{img}_{rhm}} ) = {E}_{{y}_{{img}_{rhm}} ∼ {P}_{data} ( {Y}_{{img}_{rhm}} )} {‖ {G}_{{img}_{p}} ( {F}_{{img}_{rhm}} ( {y}_{{img}_{rhm}} ) ) - {y}_{{img}_{rhm}} ‖}_{1} + {E}_{{x}_{{img}_{p}} ∼ {p}_{data} ( {X}_{{img}_{p}} )} {‖ {F}_{{img}_{r h m}} ( {G}_{{img}_{p}} ( {x}_{i m {g}_{p}} ) ) - {x}_{{img}_{p}} ‖}_{1} \qquad ( 4 )$$
wherein [symbol] _{dis}(G_{img}_{ₚ}, F_{img}_{ᵣₕₘ}) represents a standard loss function of the cycle-consistency generative adversarial network, the standard loss function is expressed as:
$${ℒ}_{c y c} ( {G}_{{img}_{p}} , {F}_{{img}_{rhm}} ) = {E}_{{x}_{{img}_{rhm} , {y}_{{img}_{rhm}}} ∼ {P}_{data} ( {X}_{{img}_{p}} , {Y}_{{img}_{rhm}} )} {‖ {F}_{{img}_{rhm}} ( {y}_{{img}_{rhm}} ) - {x}_{{img}_{p}} ‖}_{1} + {E}_{{x}_{{img}_{p}} , {y}_{{img}_{rhm}} ∼ {p}_{data} ( {X}_{{img}_{p}} , {y}_{{img}_{rhm}} )} {‖ {G}_{{img}_{p}} ( {x}_{i m {g}_{p}} ) - {y}_{{img}_{rhm}} ‖}_{1} \qquad ( 5 )$$
in the formula (1), λ and γ represent weight indicator factors, both λ and γ are positive numbers:
step S402: representing, based on the definition, an objective function of the cycle-consistency generative adversarial network as:
$${min}_{{G}_{{img}_{p}} , {F}_{{img}_{rhm}}} {min}_{{X}_{{img}_{p}} , {Y}_{{img}_{rhm}}} ℒ ( {G}_{{img}_{p}} , {F}_{{img}_{rhm}} , {Dis}_{{img}_{rhm}} , {Dis}_{{img}_{p}} ) ; \qquad ( 6 )$$
step S403: for the forward generation function G_{img}_{ₚ} and the reverse generation function F_{img}_{ᵣₕₘ}, constructing a first neural network model for training, the first neural network model comprises m₁ convolution modules, an intensive residual network composed of n₁ residual modules and m₁ deconvolution modules, both m₁ and n₁ being positive integers;
step S404: for the reverse discriminate functions Dis_{img}_{ₚ} and the forward discriminate function Dis_{img}_{ᵣₕₘ}, constructing a second neural network model for training, the second neural network model comprises m₂ convolution modules, m₂ being a positive integer;
step S405: enabling multiple image files after placement imgₚ and multiple heat map files imgᵣₕₘ capable of representing the result of FPGA routing congestion to form an overall sample set;
dividing the overall sample set into two parts of a training sample set and a verification sample set;
training the first neural network model and the second neural network model based on the training sample set, and in response to an objective function curve converges, completing the training to obtain an initial training model; and
calibrating the initial training model by using the verification sample set to obtain a final training model;
step S406: inputting the image file after placement imgₚ into the final training model to obtain the result of routing congestion prediction.

11. The FPGA routing congestion prediction method as claimed in claim 1, wherein the step S2, extracting the feature information parameters to obtain the image file after placement imgₚ comprises:
completing a placement and routing process by using an automatic placement and routing tool;
saving intermediate result information;
extracting the feature information parameters based on the intermediate result information.

12. The FPGA routing congestion prediction method as claimed in claim 1, wherein the cycle-consistency generative adversarial network model comprises a positive generative adversarial network and a negative generative adversarial network.

13. The FPGA routing congestion prediction method as claimed in claim 5, wherein the first neural network model comprises a dumbbell-shaped symmetrical structure.
